(19) United States
(12) Patent Application Publication
(10) Pub. No.: US 2011/0233404 A1
(43) Pub. Date: Sep. 29, 2011

(54) OPTICAL SWITCH WINDOW FOR UNCOOLED FPA PACKAGE

(75) Inventor: JAIME SONSTROEM, Springfield, VA (US)

(73) Assignee: UNITED STATES OF AMERICA, AS REPRESENTED BY THE SECRETARY OF ARMY, Fort Belvoir, VA (US)

(21) Appl. No.: 12/730,481

(22) Filed: Mar. 24, 2010

(51) Int. Cl. H01L 27/146; H01L 31/0232

(52) U.S. Cl. 250/332

(57) ABSTRACT

In an uncooled camera having a focal plane array and an optical lens for focusing radiation from infrared radiation sources onto the focal plane array, the improvement comprising providing a thermochromic optical switch for blocking radiation from an extremely hot infrared radiation source from reaching the focal plane array.

### GOVERNMENT INTEREST

The invention described herein may be manufactured, used, sold, imported, and/or licensed by or for the Government of the United States of America for governmental purposes without payment of any royalties thereon.

### FIELD OF THE INVENTION

The present invention generally relates to an optical switch window for an uncooled Focal Plane Array (FPA) package and in particular to a thermochromic optical switch window coated with crystalline vanadium oxide (VO₂).

### BACKGROUND OF THE INVENTION

Some micro-bolometer-based uncooled infrared focal plane arrays can be temporarily or permanently damaged if exposed to infrared radiation coming from extremely hot or bright sources.

What is needed is a low cost solution to minimize the degradation or damage to uncooled focal plane arrays from infrared radiation. Previously, it was known in U.S. Pat. No. 7,259,925 to Byong H. Aim of the Army Night Vision Laboratory that a layer of VO₂ would generally protect infrared sensors in a Forward Looking Infrared imager (FLIR) against radiation from high power lasers. But, this patent does not disclose how the VO₂ layer should be incorporated in an uncooled sensor, or how it can be designed to block radiation that is less intense than lasers, such as sunlight as a special case.

### SUMMARY OF THE INVENTION

The sensor system has a housing which contains optical elements disposed within the housing and at a first end of the housing to converge light rays entering the housing onto a focal plane. A focal plane array is disposed within an FPA package inside the sensor housing substantially coincident with the image plane. A means for protecting the sensor system from intense infrared radiation is disposed upon the window of the FPA package or between the window and the FPA. It is therefore an object of this invention to protect a focal plane array from extremely hot or bright infrared radiation sources.

This and other objects of the invention are achieved in one aspect by an uncooled camera having a focal plane array package with an optical lens for focusing infrared radiation from infrared radiation sources onto the FPA. The improvement comprises providing in addition a means for blocking radiation from an extremely hot infrared radiation source from reaching the FPA. The blocking means may be located on the window of the FPA package or between the window and the FPA.

Another embodiment of the invention is where the blocking means is a layer of VO₂.

A further embodiment of the invention involves a method for protecting an uncooled focal plane array by blocking radiation from an extremely hot infrared radiation source from reaching the focal plane array.

Additional advantages and features will become apparent as the invention becomes better understood by reference to the following detailed description when considered in conjunction with the accompanying drawings.

### BRIEF DESCRIPTION OF THE DRAWINGS

FIG. 1 shows a conventional uncooled camera with a Focal Plane Array.

FIG. 2 shows the rear area of the camera of FIG. 1 with an optical switch located on a window of Focal Plane Array.

FIG. 3 shows an FPA package with an optical switch located between the window and the Focal Plane Array.

FIG. 4 shows FIG. 3 with an exploded view of the optical switch located near the pixels of the FPA.

FIG. 5 shows the rear area of the camera of FIG. 1 in the presence of an extremely hot radiation source.

### DETAILED DESCRIPTION

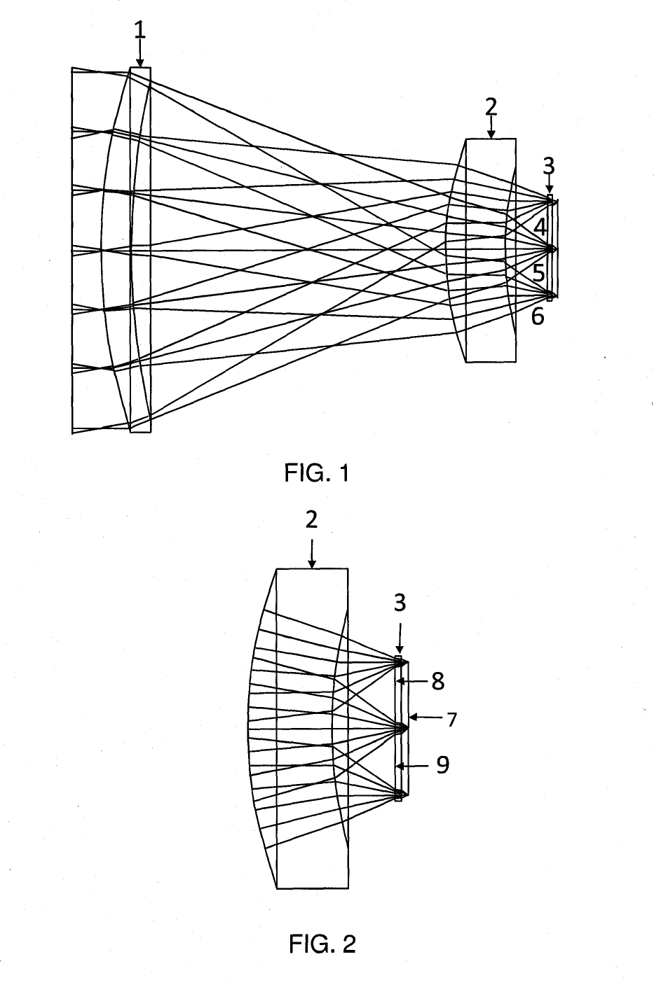

Referring to the drawing, FIG. 1 shows a conventional uncooled camera with a lens having optical elements 1, 2 and Focal Plane Array (FPA) package 3. Infrared radiation from the scene travels through the lens and is focused into the FPA package. The figure shows ray traces at three specific field angles 4, 5, 6, but those familiar with the art will recognize that in fact the entire FPA is illuminated with varying degrees of infrared radiation due to the infrared scene.

FIG. 2 focuses on the rear area from FIG. 1 and shows that the FPA package 3 is further composed of the FPA 7 and the FPA package window 8. In accordance with the invention, a means is provided for blocking radiation from an extremely hot infrared radiation source from reaching the focal plane array. The blocking means is optical switch 9 which is shown located on the rear of the FPA window, where the optical gain is the highest. The optical switch is a thin layer of crystalline VO₂, a material which undergoes a reversible semiconductor-to-metal phase transition upon heating at approximately 67 degrees Celsius. Upon switching, high quality VO₂ films (previously transparent to long wavelength infrared) become opaque, both reflecting and absorbing the incident radiation. For normal scene intensities, the infrared radiation from all fields is transmitted through the window and the VO₂ switch.

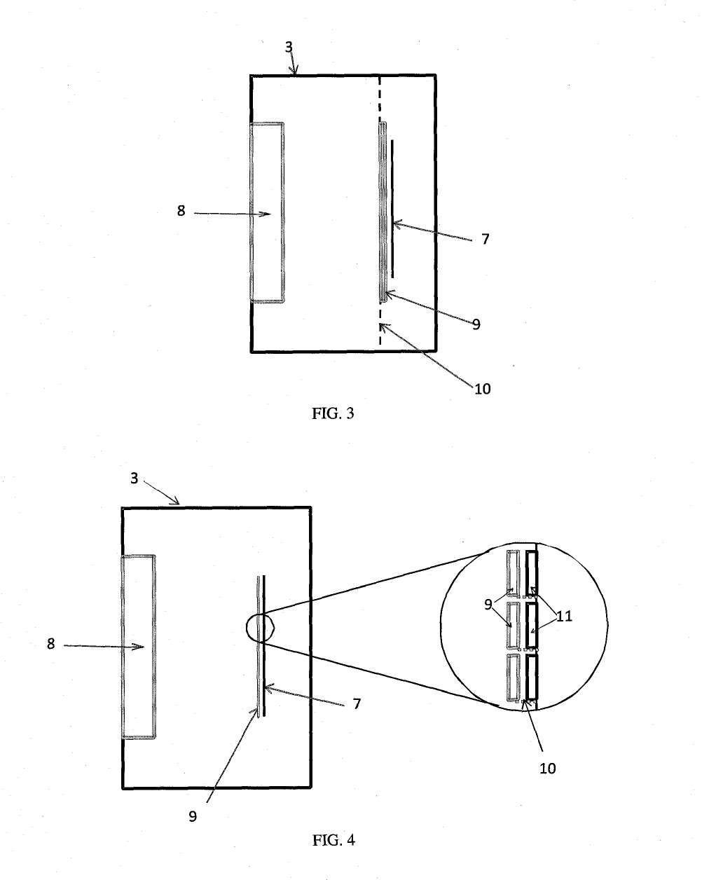

FIG. 3 discloses an FPA package 3 with window 8, FPA 7 and optical switch 9 located on thermal insulation 10 within the package between the window and the FPA.

FIG. 4 is similar to the FPA package 3 of FIG. 3 in that the VO₂ switch is between the window and the FPA. However, this is an alternate configuration, seen best in the exploded view which shows individual optical switches 9 on thermal insulation 10 in front of each individual detector pixel 11. Each optical switch is designed to have a thermal time constant in the range of milliseconds to promote heating of the optical switch and therefore the VO₂ layer to switch from a normally transparent state to an opaque state when heated by infrared radiation from an extremely hot infrared radiation source and returning to the normally transparent state when the extremely hot infrared radiation source is removed.

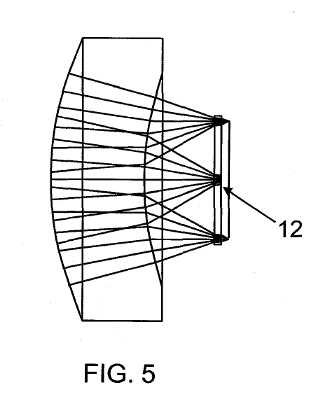

As shown in FIG. 5, if a region of the scene becomes extremely bright in the infrared, the optical switch heats up in the corresponding region of the window, and switches locally 12, blocking the intense infrared radiation from reaching the FPA.

A thin film VO₂ layer can be incorporated into the anti-reflection coating on the window of the uncooled FPA package. The window may be made out of germanium, ZnSe or other material transparent to far-infrared and amenable to the deposition of VO₂. It is near the image plane and is subject to approximately the same scene irradiance as the FPA for extended sources. The VO₂ layer is designed to absorb approximately 10% of the in-band infrared radiation. Exposure to an extremely hot source causes the film to heat beyond the transition temperature, thus switching to the reflective state. In the reflective state, the irradiance on the FPA is limited to levels below those which cause adverse effects. In the reflective state, the layer then cools until it becomes transmissive again. If the hot source of radiation is still present, the cycle repeats and thus, the device is self-regulating.

It is obvious that many modifications and variations of the present invention are possible in light of the above teachings. It is therefore to be understood that within the scope of the appended claims, the present invention may be practiced otherwise than as described.

Although the invention has been shown and described with respect to certain preferred embodiments, it is obvious that equivalent alterations and modifications will occur to others skilled in the art upon the reading and understanding of this specification and the annexed drawings. In particular with regard to the various functions performed by the above described components (assemblies, devices, sensors, circuits, etc), the terms (including a reference to a “means”) used to describe such components are intended to correspond, unless otherwise indicated, to any component which performs the specified function of the described component (i.e., functionally equivalent), even though not structurally equivalent to the disclosed structure which performs the function in the herein illustrated exemplary embodiments of the invention. For example, the VO₂ optical switch can also protect the FPA from CW and pulsed inband lasers. In addition, while a particular feature of the invention may have been disclosed with respect to only one of several embodiments, such feature may be combined with one or more other features of the other embodiments as may be desired and advantageous for any given or particular application.

What is claimed is:

1. An uncooled camera having a focal plane array and an optical lens for focusing infrared radiation from infrared radiation sources onto the focal plane array, and
means for blocking intense infrared radiation from an extremely hot infrared radiation source from reaching the focal plane array.

2. The uncooled camera recited in claim 1 wherein the focal plane array is part of a focal plane array package.

3. The uncooled camera recited in claim 2 wherein the focal plane array package has a window made out of material transparent to far-infrared.

4. The uncooled camera recited in claim 3 wherein the window is made out of germanium.

5. The uncooled camera recited in claim 3 wherein the window is made out of ZnSe.

6. The uncooled camera recited in claim 3 wherein the window has an anti-reflection coating.

7. The uncooled camera recited in claim 1, wherein the blocking means is a thin film layer of VO₂ located on the FPA window.

8. The uncooled camera recited in claim 7, wherein a thin layer of VO₂ is incorporated into the anti-reflective coating to act as a blocking means.

9. The uncooled camera recited in claim 8 wherein the thin film layer of VO₂ is located on the rear of the FPA window where the optical gain is the highest

10. An uncooled camera having a focal plane array package composed of a focal plane array and a focal plane array package window,
an optical lens for focusing infrared radiation from infrared radiation sources onto the focal plane array, and
a VO₂ optical switch coating disposed on the focal plane array package window to block radiation from an extremely hot infrared radiation source from reaching the focal plane array, the optical switch coating designed to switch from a normally transparent state to an opaque state when heated by infrared radiation from an extremely hot infrared radiation source and returning to the normally transparent state when the extremely hot infrared radiation source is removed.

11. The uncooled camera recited in claim 10, wherein the camera contains an optical lens transmitting midwave (3-5 microns) and long wave (8-14 microns) radiation, wherein the VO₂ optical switch coating is designed to absorb midwave radiation and to transmit long wave radiation, and wherein said coating further contains another coating to reflect midwave radiation for solar protection.

12. An uncooled camera recited in claim 1 wherein the blocking means is
a VO₂ optical switch located within the focal plane array package between the window and the FPA to block radiation from an extremely hot infrared radiation source from reaching the focal plane array, the optical switch designed to have a thermal time constant in the range of milliseconds to promote heating of the optical switch and therefore the VO₂ layer to switch from a normally transparent state to an opaque state when heated by infrared radiation from an extremely hot infrared radiation source and returning to the normally transparent state when the extremely hot infrared radiation source is removed.

13. The uncooled camera recited in claim 12, wherein a VO₂ optical switch is located in front of each individual detector pixel.

14. A method of protecting a focal plane array comprising the step of:
focusing infrared radiation from infrared radiation sources onto a focal plane array; and
blocking intense infrared radiation from an extremely hot infrared radiation source from reaching the focal plane array.

15. The method recited in claim 14, wherein the focal plane array is part of a focal plane array package having a window coated with an anti-reflection coating, and wherein the blocking of the infrared radiation is achieved by incorporating a thin film layer of VO₂ into the anti-reflection coating.

16. The method recited in claim 14, wherein the focal plane array is part of a focal plane array package having a window made out of material transparent to far-infrared, and wherein the blocking of the infrared radiation is achieved by disposing an optical switch coating on the FPA window.

17. The method recited in claim 16 wherein the optical switch coating is a thin film layer of VO₂.

18. The method recited in claim 17, wherein the layer of VO₂ is disposed on the rear of the FPA window where the optical gain is the highest.
